(19) United States
(12) Patent Application Publication
(10) Pub. No.: US 2006/0255407 A1
(43) Pub. Date: Nov. 16, 2006

(54) Semiconductor device and manufacturing method of the same

(76) Inventor: Hiroyasu Ishida, Gunma (JP)

Correspondence Address: MORRISON & FOERSTER LLP, 1650 TYSONS BOULEVARD, SUITE 300, MCLEAN, VA, 22102, US

(21) Appl. No.: 11/409,275

(22) Filed: Apr. 24, 2006

(30) Foreign Application Priority Data
Apr. 28, 2005 (JP) 2005-130762

(51) Int. Cl. H01L 27/12

(52) U.S. Cl. 257/347

(57) ABSTRACT

In a peripheral insulating film in a peripheral region, concave parts are provided. At least one of the concave parts is made to have an opening as a contact hole with an Al wiring layer, and a plurality of contact holes may be provided. Accordingly, frictions between the Al wiring layer and the peripheral insulating film are increased. Thus, occurrence of Al slide can be suppressed.

### BACKGROUND OF THE INVENTION

1. Field of the Invention

The present invention relates to a semiconductor device and a manufacturing method thereof, and more particularly relates to a semiconductor device effective in preventing Al slide and a manufacturing method thereof.

2. Description of the Related Art

FIG. 8 shows a cross-sectional view around a peripheral region of a conventional semiconductor chip. In an element region 71 of a semiconductor chip 80, a MOSFET cell 73 having a trench structure, for example, is provided. Specifically, a semiconductor substrate is obtained by laminating an n−type epitaxial layer 52 on an n+type silicon semiconductor substrate 51 and forming a drain region D. Thereafter, a channel layer 54 is provided on a surface of the semiconductor substrate, and trenches 58 are provided. In each of the trenches 58, a gate electrode 63 is provided with a gate insulating film 61 interposed therebetween. On the substrate surface between the trenches 58, a source region 65 and a body region 64 are disposed.

On a surface of the element region 71, a source electrode 67 is provided and extended to a peripheral region 72. A gate wiring 68 is connected to a polysilicon 63p connected to the gate electrode 63. Moreover, a high-concentration impurity region 70 is provided in an outermost periphery of the peripheral region 72 in order to prevent inversion, and a shield metal 69 comes into contact therewith. This technology is described for instance in Japanese Patent Application Publication No. 2005-101334.

As shown in FIG. 8, in the peripheral region 72 around the element region 71, an insulating film 62, which is obtained by combining a part of an interlayer insulating film 66, a part of the gate insulating film 61 and an insulating film that are a mask for forming a guard ring 53 and a mask for forming the high-concentration impurity region 70 and the like, is disposed on the semiconductor substrate. The insulating film 62 is an oxide film.

Subsequently, a metal layer 60 including the shield metal 69, the gate wiring 68 and the like is provided so as to cover the insulating film 62 and the high-concentration impurity region 70. The metal layer 60 is an Al wiring layer, which is the same as the source electrode 67.

The entire surface of the semiconductor chip 80 is covered with a surface protection film (a passivation film) 74. Furthermore, the semiconductor chip 80 is fixed onto an island (not shown) of a lead frame and is covered with a resin layer 75 which forms a package together with the island. Specifically, as shown in FIG. 8, the surface protection film 74 and the resin layer 75 are disposed on the Al wiring layer 60.

One of the causes of failure of the semiconductor chip 80 due to a mechanical stress received from the resin layer 75 is Al slide. The Al slide is a phenomenon that, in the case where the semiconductor chip 80 receives a thermal stress from the outside, the Al wiring layer 60, which has received the stress from the resin layer 75 through the surface protection film 74, moves (slides).

There are various thermal stresses from the outside. For example, a temperature cycle test, a thermal shock test and the like are thermal stresses. Particularly, if thermal stresses are repeatedly applied from the outside such as the temperature cycle test, cracks are generated in the surface protection film. Thus, there is a problem that occurrence of the Al slide is accelerated.

The Al slide occurs in a spot where the Al wiring layer 60 is disposed. The spot includes the shield metal 69, the gate wiring 68 and the like, which are formed in the peripheral region 72 of the semiconductor chip 80. Particularly, the shield metal 69 is disposed in a portion where there are small steps with respect to a width of the shield metal 69. Moreover, in FIG. 8, there is only one step S′ covered with the shield metal 69. A relatively flat surface and a small friction also are the reasons why the Al slide cannot be suppressed.

The gate wiring 68 and the source electrode 67 are provided so as to be adjacent to the shield metal 69. Since the gate wiring 68 and the source electrode 67 are also part of the Al wiring layer 60, the Al slide occurs. Therefore, when the shield metal 69 slides as indicated by the arrow in FIG. 8, the shield metal 69 comes into contact with the gate wiring 68 provided adjacent thereto to cause a leak between gate and drain. Moreover, there is also a case where the gate wiring 68 comes into contact with the source electrode 67 to cause a leak between gate and source.

Moreover, in the case where there is a large mechanical stress, there is also a problem that the Al slide applies a stress to the surface protection film 74 and causes cracks therein. When water and particles from the outside enter through the cracks of the surface protection film 74, the Al wiring layer 60 is corroded to cause disconnection failure. Moreover, a leak failure between wirings may be caused by the water and impurities, which is problematic in terms of reliability.

### SUMMARY OF THE INVENTION

The present invention provides a semiconductor device that includes a semiconductor substrate comprising an element region and a peripheral region surrounding the element region, the device comprising an insulating film disposed on the peripheral region and having a plurality of concave portions over the peripheral region, a metal layer disposed on the insulating film, a protection film disposed on the metal layer, and a resin layer disposed on the protection film.

The present invention also provides a semiconductor device that includes a semiconductor chip comprising a semiconductor substrate comprising an element region and a peripheral region surrounding the element region, an insulating film disposed on the peripheral region and having a plurality of concave portions over the peripheral region, a metal layer disposed on the insulating film, a protection film covering the semiconductor chip, a lead frame comprising an island portion on which the semiconductor chip is fixed, and a resin layer covering the island portion and the semiconductor chip.

The present invention further provides a method of manufacturing a semiconductor device. The method includes forming an element region and a peripheral region on a semiconductor substrate, forming an insulating film on the peripheral region, forming concave portions in the insulating film over the peripheral region, forming a metal layer to cover the insulating film and the concave portions, forming a protection film on the metal layer, and forming a resin layer on the protection film.

### BRIEF DESCRIPTION OF THE DRAWINGS

FIG. 1 is a plan view showing a semiconductor device of a preferred embodiment of a present invention.

FIG. 2 is a cross-sectional view showing the semiconductor device of the preferred embodiment of the present invention.

FIG. 3A is a side view, FIG. 3B is a back view and FIG. 3C is a cross-sectional view showing the semiconductor device of the preferred embodiment of the present invention.

FIG. 4A is a side view, FIG. 4B is a back view and FIG. 4C is a cross-sectional view showing the semiconductor device of the preferred embodiment of the present invention.

FIGS. 5A to 5C are cross-sectional views showing a method of manufacturing a semiconductor device of the preferred embodiment of the present invention.

FIG. 6 is a cross-sectional view showing the method of manufacturing a semiconductor device of the preferred embodiment of the present invention.

FIGS. 7A and 7B are cross-sectional views showing the method of manufacturing a semiconductor device of the preferred embodiment of the present invention.

FIG. 8 is a cross-sectional view showing a conventional semiconductor device.

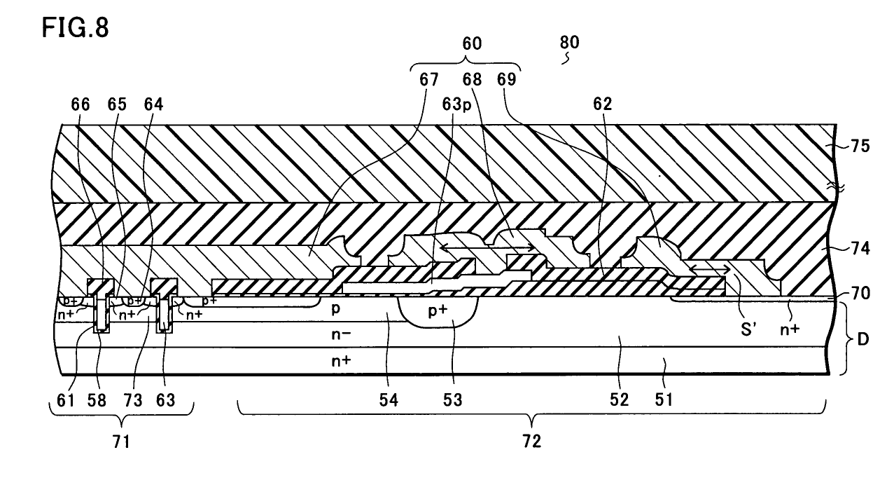

### DESCRIPTION OF THE EMBODIMENTS

An embodiment of the present invention will be described in detail by taking the case where an n-channel trench MOSFET is formed in an element region, as an example.

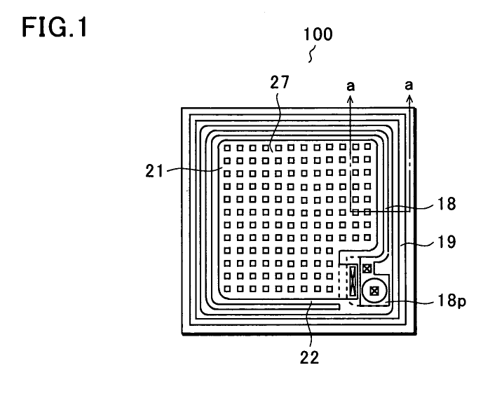

FIG. 1 is a plan view showing a structure of a semiconductor device of the embodiment of the present invention. Note that, here, a source electrode on a surface is omitted.

As shown in FIG. 1, in an element region 21 of a semiconductor chip 100, a number of MOSFET cells 27 are disposed. The source electrode is provided while being connected to a source region of each of the cells 27 on the element region 21. A gate wiring 18 is connected to a gate electrode, extended to a peripheral region 22 which surrounds the element region 21, and connected to a gate pad electrode 18p.

Moreover, in an outermost periphery of the semiconductor chip 100, a high-concentration impurity region (not shown here) which is called annular is provided to prevent inversion of impurities on a substrate surface. The annular comes into contact with a shield metal 19 which covers a surface thereof.

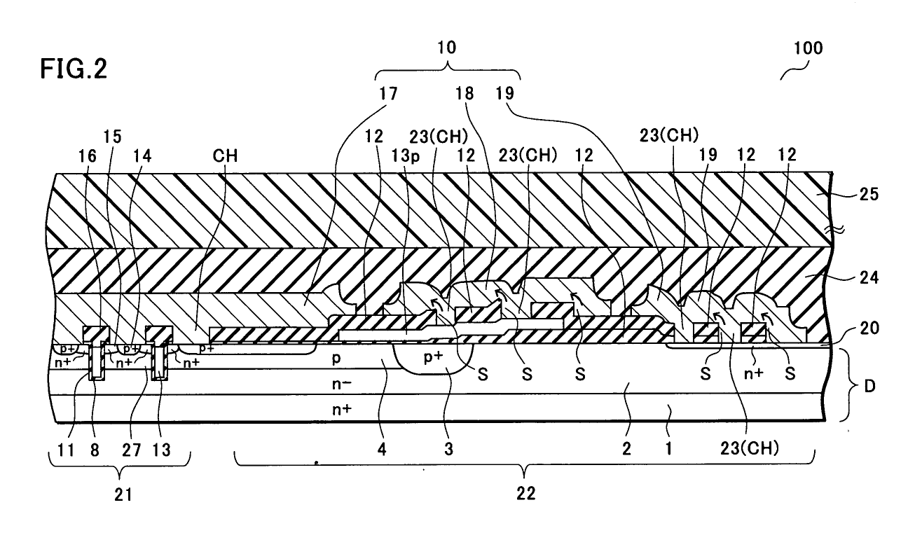

FIG. 2 is a cross-sectional view along the line a-a in FIG. 1.

As shown in FIG. 2, a semiconductor substrate is obtained by laminating an n−type epitaxial layer 2 on an n+type silicon semiconductor substrate 1 and forming a drain region D. A channel layer 4 is a diffusion region obtained by selectively implanting p−type boron or the like into a surface of the drain region D.

A trench 8 penetrates the channel layer 4 and reaches the n−type epitaxial layer 2. The trenches 8 are generally patterned into a lattice shape or a stripe shape on a surface of the semiconductor substrate. The trench 8 has a gate oxide film 11 provided on its inner wall. A thickness of the gate oxide film 11 is several hundred Å according to a drive voltage. In the trench 8, polysilicon is buried. In order to achieve a low resistance, n−type impurities are implanted into the polysilicon. Thus, a gate electrode 13 is formed. The gate electrode 13 comes into contact with a gate wiring 18 through a polysilicon 13p drawn out onto the substrate.

A source region 15 is an n+type impurity region provided in a surface of the channel layer 4 adjacent to the trench 8, and comes into contact with a source (pad) electrode 17 which covers the element region 21. Moreover, in the surface of the channel layer 4 between the source regions 15 adjacent to each other, a body region 14 that is a p+type impurity region is provided. Thus, an electric potential at the substrate is stabilized.

The source electrode 17 is an Al wiring layer and comes into contact with the source region 15 and the body region 14 through a contact hole CH between interlayer insulating films 16.

The semiconductor chip 100 includes the element region 21 and the peripheral region 22. The element region 21 is a region in which the MOSFET cells 27 are disposed, and the peripheral region 22 is a region which surrounds the outside of the element region 21 and reaches an end of the semiconductor chip. In the substrate surface in the peripheral region 22, a guard ring 3 that is a p+type impurity region and an annular 20 that is an n+type impurity region are provided. The guard ring 3 is positioned at an end of the channel layer 4 and suppresses an electric field concentration by relaxing a curvature of a depletion layer in a peripheral end of the channel layer 4. Moreover, the annular 20 prevents inversion of impurities in the substrate surface as described above.

Above the guard ring 3, the polysilicon 13p is disposed, which is obtained by drawing out the gate electrode 13 in the element region 21. The polysilicon 13p comes into contact with the gate wiring 18 provided thereabove. Moreover, the annular 20 comes into contact with the shield metal 19 provided thereon.

The guard ring 3 is provided along the end of the channel layer 4 below the gate wiring 18. The annular 20 is provided along the shield metal 19. Shapes of the guard ring 3 and the annular 20 are both circular, as is the case with the shield metal 19n shown in FIG. 1. Accordingly, in this embodiment, the guard ring 3, the gate wire 18 and the shield metal 19 are placed in the peripheral region 22.

The source electrode 17, the gate wiring 18 and the shield metal 19 are formed of a same metal layer 10. To be more specific, the metal layer 10 is an Al wiring layer. Moreover, although not shown in FIG. 2, the metal layer 10 may have a configuration in which a barrier metal layer is disposed below the Al wiring layer.

Here, a peripheral insulating film 12 is a collective term for insulating films disposed in the peripheral region 22. Specifically, the peripheral insulating film 12 is a part of the gate oxide film 11 and the interlayer insulating film 16, which remain in the peripheral region 22. Moreover, the peripheral insulating film 12 is an insulating film which remains in the peripheral region 22 and serves as a mask for impurity diffusion in the channel layer 4, the guard ring 3, the annular 20 and the like. In this embodiment, the peripheral insulating film 12 is an oxide film such as a BPSG (boron phosphorus silicate glass) film, a thermal oxide film and NSG (non-doped silicate glass) film or PSG (phosphorus silicate glass) film.

In the peripheral insulating film 12 below the shield metal 19, concave parts 23 are provided. A plurality of the concave parts 23 are provided below the shield metal 19, and at least one of the concave parts 23 is a contact hole CH by completely removing the peripheral insulating film 12. In FIG. 2, two concave parts 23 are provided below the shield metal 19 and are both serve as contact holes CH between the annular 20 and the shield metal 19. However, if at least one of the concave parts 23 serves as the contact hole CH, the other concave parts 23 may have the peripheral insulating film 12 remaining at bottoms thereof.

Similarly, also in the peripheral insulating film 12 below the gate wiring 18, the concave parts 23 are provided. Here, a plurality of the concave parts 23 are also provided, and at least one of the concave parts 23 is a contact hole CH by completely removing the peripheral insulating film 12. In FIG. 2, the two concave parts 23 are provided below the gate wiring 18 and both serve as contact holes CH between the polysilicon 13p and the gate wiring 18.

On the Al wiring layer, for example, a nitride film to be a surface protection film (a passivation film) 24 is provided. The surface protection film 24 covers the entire surface of the semiconductor chip except for regions which will be fixed bonding wires or the like.

Furthermore, on the surface protection film 24, a mold resin layer 25 is provided. The mold resin layer 25, to be described later, integrally covers the semiconductor chip 100 and a lead frame and forms a package.

When a thermal stress from the outside, such as a temperature cycle test, is applied to the semiconductor device, stresses are generated between the respective layers since the semiconductor chip 100, the surface protection film 24 and the mold resin layer 25 forming the package have different thermal expansion coefficients, respectively. At the time of a low-temperature storage, a contraction stress of the mold resin layer 25 acts on the chip 100 and the Al wiring layer 10 moves toward the center of the chip 100. At the time of a high-temperature storage, an expansion stress of the mold resin layer 25 acts on the chip 100 and the Al wiring layer 10 moves toward the end of the chip 100.

Moreover, cracks in the surface protection film 24 have a close relationship with Al slide. For example, even if a thermal stress is applied from the outside and the Al wiring layer 10 receives the thermal stress from the mold resin layer 25, the surface protection film 24 returns to its original state (elastic deformation) at the point where the thermal stress is released if there is no defects in the surface protection film 24. Accordingly, no Al slide phenomenon is observed.

However, if thermal stresses are repeatedly applied from the outside, such as the temperature cycle test, and cracks are generated in the surface protection film 24 due to differences in the thermal expansion coefficient, the surface protection film 24 no longer returns to its original state (plastic deformation). As a result, the Al slide phenomenon occurs.

Consequently, in this embodiment, in the case where the peripheral insulating film 12, the Al wiring layer 10, the surface protection film 24 and the mold resin layer 25 are laminated in the peripheral region 22 of the semiconductor chip 100, the concave parts 23 are provided in the peripheral insulating film 12.

Below the shield metal 19, for example, two concave parts 23 are provided. Thus, it is possible to increase the number of steps S and to increase frictions between the Al wiring layer 10 and the peripheral insulating film 12 (see the arrows in FIG. 2). Specifically, even if the mold resin layer 25 contracts by the thermal stress from the outside, occurrence of the Al slide can be suppressed.

Here, a thickness of the peripheral insulating film 12 is approximately 1.2 μm. Therefore, a depth of the concave part 23 in this embodiment is 1.2 μm and an opening width thereof is, for example, 4 μm. However, the concave parts 23 are intended to increase the frictions between the Al wiring layer 10 and the peripheral insulating film 12 by use of the steps S. Specifically, it is not required to make the concave parts 23 to have a depth that exposes the layer below the peripheral insulating film 12, and the opening width can also be appropriately selected.

However, in at least one of the concave parts 23, the peripheral insulating film 12 is completely removed. Thus, the contact hole CH between the shield metal 19 and the annular 20 or the contact hole CH between the gate wiring 18 and the polysilicon 13p is formed.

Moreover, by similarly providing the concave parts 23 below the gate wiring 18, occurrence of the Al slide can be suppressed and it is possible to avoid the leak between gate and drain and the leak between gate and source.

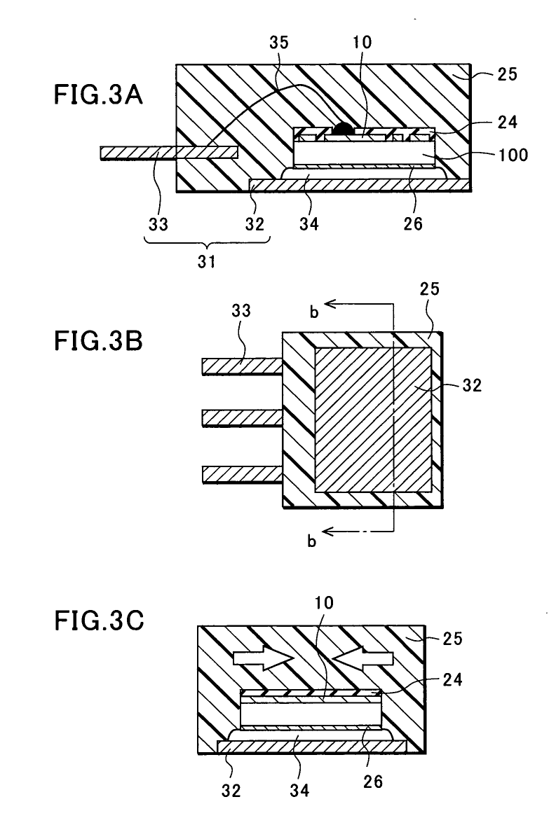

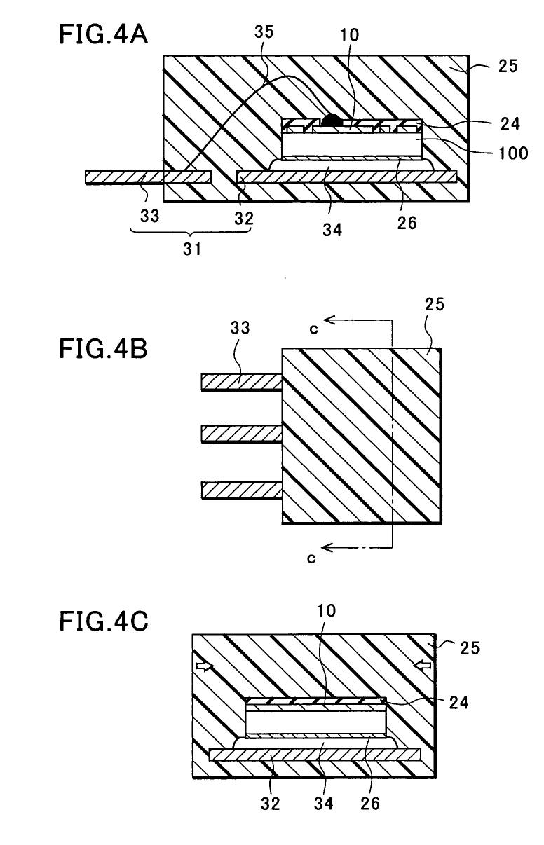

FIGS. 3A to 3C are views showing the semiconductor chip 100 mounted in a package. FIG. 3A is a side view, FIG. 3B is a back view and FIG. 3C is a cross-sectional view along the line b-b in FIG. 3B. Moreover, for comparison, FIGS. 4A to 4C show a mounting example of a full mold type. FIG. 4A is a side view, FIG. 4B is a back view and FIG. 4C is a cross-sectional view along the line c-c in FIG. 4B.

As shown in FIG. 3A, a drain electrode 26 is formed on a rear surface of the semiconductor chip 100 described above, and the chip 100 is fixed and mounted on an island 32 of a lead frame 31, for example, by use of a conductive adhesive 34 or the like. The surface of the semiconductor chip 100 is covered with the surface protection film 24, and the Al wiring layer (electrode pad) 10, which is exposed from an opening in the surface protection film 24, is connected to a lead 33 through a bonding wire 35 or the like. The mold resin layer 25 integrally covers the semiconductor chip 100 and the island 32 and forms the package. However, a rear surface of the island 32, on which the semiconductor chip 100 is not fixed, is exposed from the mold resin layer 25 (see FIG. 3B). A package size is, for example, 10 mm×15 mm.

A semiconductor device having a high power dissipation (PD) (a tolerance for heat generated during conduction) is required to have good radiation property. Thus, the full mold type mounting is not adopted but mounting is performed by exposing the rear surface of the island 32 as shown in FIG. 3B or by exposing the island only in a holding part such as a screw.

However, as shown in FIGS. 3B and 3C, in such a type of mounting, the rear surface of the island 32 is exposed and the mold resin layer 25 is only attached to a periphery of the island 32. Specifically, as indicated by the arrows in FIG. 3C, if the mold resin layer 25 contracts by a thermal stress from the outside, contraction of the mold resin layer 25 is hardly restricted by the island 32. Therefore, a contraction factor is increased, and a rate of occurrence of Al slide is increased. Furthermore, in the case of a large package size (for example, 10 mm×15 mm), the Al slide is likely to occur.

Meanwhile, FIGS. 4A to 4C show a mounting example which is called full mold type. In the full mold type mounting, the mold resin layer 25 integrally covers the island 32 including the rear surface thereof and the semiconductor chip 100. In the case of such mounting, even if the mold resin layer 25 contracts by a thermal stress from the outside, the Al slide is relatively less likely to occur. This is because contraction (the arrows in FIG. 4C) of the mold resin layer 25 is restricted by the island 32 disposed in the mold resin layer 25.

This embodiment is effective particularly for the case of the mounting as shown in FIGS. 3A to 3C, which is not the full mold type, in suppressing the Al slide.

Next, with reference to FIGS. 5 to 7 and FIG. 2, description will be given of a method of manufacturing the semiconductor device described above.

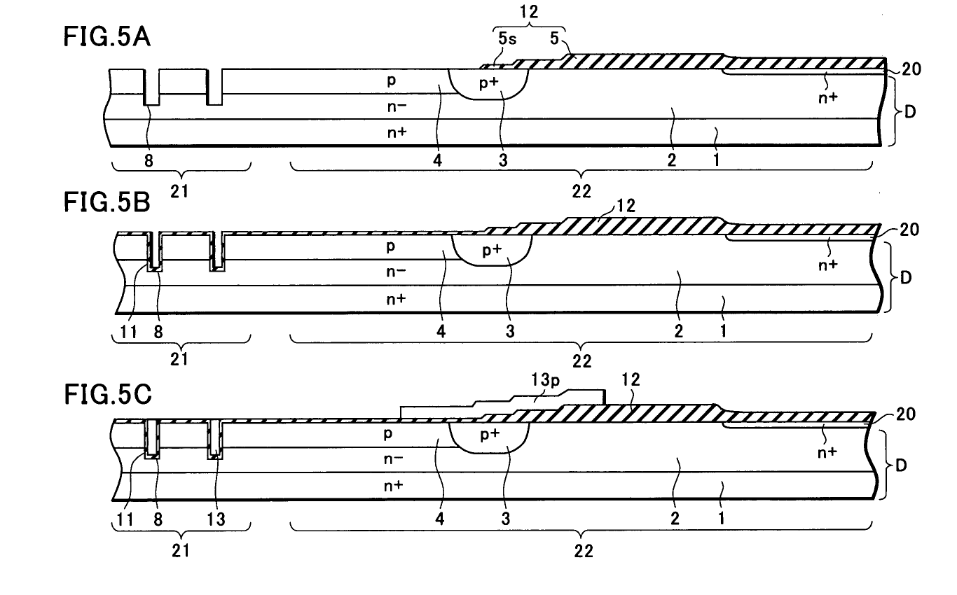

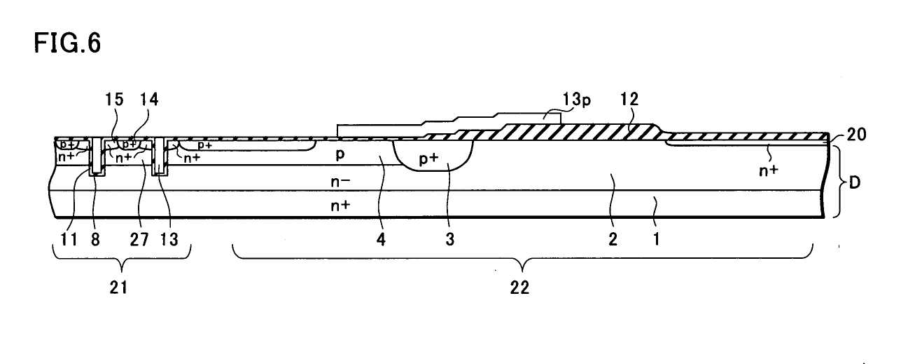

First step (FIGS. 5 and 6): A drain region D is formed by laminating an n−type epitaxial layer 2 on an n+type silicon semiconductor substrate 1. By use of an oxide film (not shown) as a mask, high-concentration boron is implanted and diffused in an end of a region to be a channel layer. Thus, a guard ring 3 is formed. Moreover, by use of an oxide film (not shown) as a mask, high-concentration n−type impurities are ion-implanted into an outermost periphery of a peripheral region 22. Thus, a high-concentration impurity region (annular) 20 is formed.

After a thermal oxide film 5s is formed on a surface, the oxide film in a portion of the channel layer to be formed is etched. After boron is implanted by a dose of 1.0×10¹³ cm⁻², for example, into the entire surface, boron is diffused to form a p−type channel layer 4. The guard ring 3 relaxes an electric field concentration at the end of the channel layer 4 and may not be provided if there is no influence on characteristics.

By use of a CVD method, a CVD oxide film 5 made of NSG (non-doped silicate glass) is formed on the entire surface. Thereafter, a mask made of a resist film is provided except for trench openings in an element region 21. The CVD oxide film 5 is provided so as to also cover the thermal oxide film 5s in the peripheral region 22 of the substrate. The CVD oxide film 5 is combined with the thermal oxide film 5s and the oxide films used as the masks for the guard ring 3 and the annular 20. Thus, a peripheral insulating film 12 is obtained. Thereafter, the CVD oxide film 5 in the element region 21 is dry-etched and partially removed to form trench openings in which the channel layer 4 is exposed.

Subsequently, by using the CVD oxide film 5 as a mask, the silicon semiconductor substrate in the trench openings is dry-etched with CF and HBr gas. Thus, trenches 8 are formed, which penetrate the channel layer 4 and reach the n−type epitaxial layer 2 (FIG. 5A).

An oxide film (not shown) is formed on inner walls of the trenches 8 and on a surface of the channel layer 4 by dummy oxidation. Thus, an etching damage in dry etching is removed. Thereafter, the oxide film described above and the CVD oxide film 5 are removed by etching.

Furthermore, by oxidizing the entire surface, a gate oxide film 11 is formed to have a thickness of about 300 Å to 700 Å, for example, according to a drive voltage, on the inner walls of the trenches 8. The surface of the peripheral region 22 is also oxidized and combined with the peripheral insulating film 12 (FIG. 5B).

A polysilicon layer is deposited on the entire surface, and dry etching is performed by providing a mask only above the guard ring 3. The polysilicon layer may be a layer obtained by depositing polysilicon containing impurities or may be a layer obtained by implanting impurities after non-doped polysilicon is deposited. Thus, gate electrodes 13 are formed, which are buried in the trenches 8. In the peripheral region 22, a polysilicon 13p is patterned, which is obtained by drawing out the gate electrode 13 (FIG. 5C).

Thereafter, in order to stabilize an electric potential of the substrate, a mask made of a resist film (not shown), in which a formation region of a body region is exposed, is provided and boron is selectively ion-implanted by a dose of 2.0×10¹⁵ cm⁻², for example.

By use of a new resist film (not shown), arsenic is ion-implanted by a dose of about 5.0×10¹⁵ cm⁻², for example, into a source region to be formed. After the resist film is removed, impurities are diffused by heat treatment to form an n+type source region 15 and a body region 14.

Thus, a region surrounded by the trenches 8 serves as a MOSFET cell 27. Accordingly, the element region 21, in which a number of the cells 27 are disposed, and the peripheral region 22, which reaches an end of a semiconductor chip from outside of the element region 21, are formed (FIG. 6).

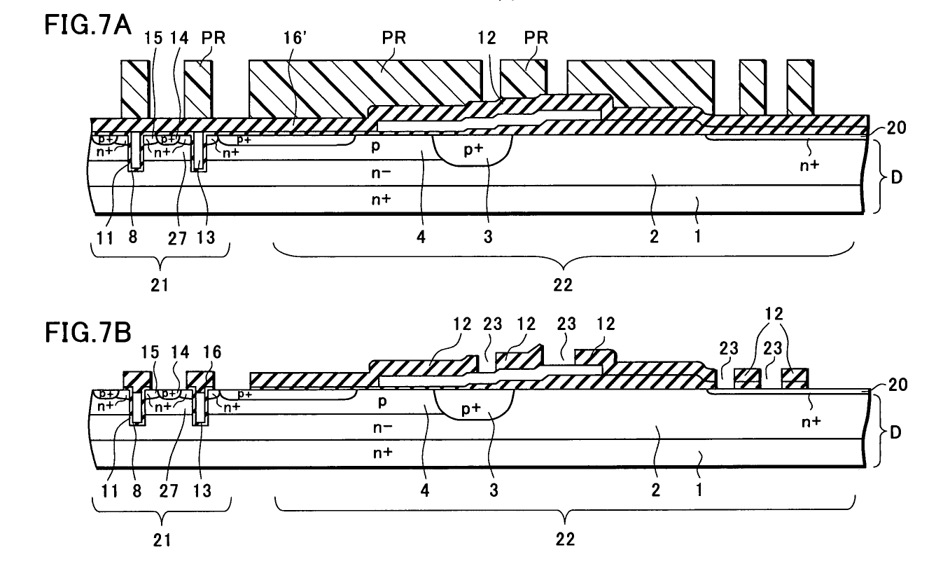

Second step (FIGS. 7A and 7B): An insulating film 16′ made of a NSG or PSG (not shown) layer and a BPSG layer are laid on the entire surface by use of the CVD method. The insulating film 16′ is also formed on the peripheral region 22 and is combined with the peripheral insulating film 12. By use of a resist film, a mask is provided so as to leave the insulating film 16′ on the gate electrode 13 in the element region 21, and the peripheral insulating film 12 having a desired pattern in the peripheral region 22 (FIG. 7A).

In the element region 21, the insulating film 16′ is etched to form an interlayer insulating film 16 which covers the gate electrode 13.

In this event, concave parts 23 are simultaneously formed in the peripheral insulating film 12. Specifically, two concave parts 23, for example, are formed in the peripheral insulating film 12 positioned below a formation region of a shield metal. At least one of the concave parts 23 is etched so as to expose the substrate surface, in order to make the concave part 23 serve as a contact hole CH with the shield metal formed thereabove. Here, since the etching step (the step of etching the insulating film 16′) is performed once, the substrate surface (the annular 20) is exposed in all of the plurality of concave parts 23 in the formation region of the shield metal. Note that, in the case where the concave parts 23 serve as contact holes CH, etching is performed under conditions according to an insulating film having a largest thickness.

Furthermore, the two concave parts 23, for example, are also formed in the peripheral insulating film 12 below a formation region of a gate wiring. The concave parts 23 described above are also formed in the same step as that of etching the insulating film 16′. Thus, the concave parts 23 are both serve as contact holes CH with the polysilicon 13p (FIG. 7B).

Third step (FIG. 2): Thereafter, aluminum or the like is attached to the entire surface by use of a sputtering apparatus. Thus, an Al wiring layer 10 is formed. In the element region 21, a source (pad) electrode 17 is patterned, which comes into contact with the source region 15 and the body region 14. Moreover, at the same time, a gate wiring 18 and a shield metal 19 are formed. Thereafter, the concave parts 23 are covered with the Al wiring layer 10.

Furthermore, a drain electrode (not shown) is formed on a rear surface of the substrate, and a surface protection film is formed on the substrate surface. Thereafter, the substrate is divided into individual semiconductor chips by dicing, and a rear surface (the drain electrode) of the semiconductor chip is fixed onto an island of a lead frame. After desired wiring is performed by use of bonding wires and the like, the semiconductor chip and the lead frame are collectively covered with a mold resin layer. In this embodiment, the following type of mounting is adopted. Specifically, a rear surface of the island, to which the semiconductor chip is not fixed, is exposed from the mold resin layer. Thus, a final structure shown in FIGS. 2 and 3A is obtained.

Note that, in the embodiment of the present invention, the description was given by taking the n-channel MOSFET as an example. However, the embodiment of the present invention is similarly applicable to a p-channel MOSFET having a conductivity type inverted.

Moreover, the description was given by taking the shield metal 19 and the gate wiring 18 of the MOSFET as the Al wiring layer. However, the Al wiring layer is not limited thereto. For example, in the element region, an insulated gate semiconductor element such as an IGBT (insulated gate bipolar transistor), a schottky barrier diode or the like may be adopted. Specifically, in a semiconductor device having an Al wiring layer provided in a peripheral region with an insulating film interposed therebetween, occurrence of Al slide can be suppressed by providing concave parts in the insulating film. It is also possible that all of the concave parts 23 include the peripheral insulating film 12 so that any of them does not operate a contact hole.

According to the structure of the embodiment of the present invention, the plurality of concave parts are provided in the insulating film below the Al wiring layer, and frictions caused by steps are increased. Thus, it is possible to suppress occurrence of Al slide due to a thermal stress such as a temperature cycle test.

Moreover, the concave parts can be formed simultaneously with formation of contact holes in the element region. Specifically, the concave parts can be formed only by changing masks. Thus, it is possible to provide a method of manufacturing a semiconductor device suppressing the Al slide, with preventing an increase in the number of manufacturing steps or in the number of masks.

What is claimed is:

1. A semiconductor device comprising a semiconductor substrate comprising an element region and a peripheral region surrounding the element region, the device comprising:
an insulating film disposed on the peripheral region and having a plurality of concave portions over the peripheral region;
a metal layer disposed on the insulating film;
a protection film disposed on the metal layer; and
a resin layer disposed on the protection film.

2. A semiconductor device comprising:
a semiconductor chip comprising a semiconductor substrate comprising an element region and a peripheral region surrounding the element region;
an insulating film disposed on the peripheral region and having a plurality of concave portions over the peripheral region;
a metal layer disposed on the insulating film;
a protection film covering the semiconductor chip;
a lead frame comprising an island portion on which the semiconductor chip is fixed; and
a resin layer covering the island portion and the semiconductor chip.

3. The semiconductor device of claim 2, wherein the resin layer is configured not to cover a rear surface of the island portion.

4. The semiconductor device of claim 1 or 2, wherein at least one of the concave portions penetrates through the insulating film so that the metal layer is in contact with the substrate or a conductive layer formed on the substrate.

5. The semiconductor device of claim 1 or 2, wherein the metal layer comprises an aluminum wiring layer.

6. The semiconductor device of claim 4, further comprising an impurity region formed in the peripheral region, wherein the metal layer is in contact with the impurity region.

7. The semiconductor device of claim 4, wherein the metal layer is connected with the element region through the conductive layer.

8. The semiconductor device of claim 1 or 2, wherein the insulating film comprises an oxide film.

9. The semiconductor device of claim 1 or 2, further comprising an electrode disposed on a rear surface of the substrate.

10. The semiconductor device of claim 1 or 2, further comprising an insulated gate element having a trench structure formed in the element region.

11. A method of manufacturing a semiconductor device, comprising:
forming an element region and a peripheral region on a semiconductor substrate;
forming an insulating film on the peripheral region;
forming concave portions in the insulating film over the peripheral region;
forming a metal layer to cover the insulating film and the concave portions;
forming a protection film on the metal layer; and
forming a resin layer on the protection film.

12. The method of claim 11, further comprising forming contact holes so that the metal layer is in contact with the element region, wherein the concave portions are formed by the same process step in which the contact holes are formed.
